(19) United States
(12) Patent Application Publication
(10) Pub. No.: US 2024/0304712 A1
(43) Pub. Date: Sep. 12, 2024

(54) SEMICONDUCTOR STRUCTURE AND PREPARATION METHOD THEREOF

(71) Applicant: Enkris Semiconductor, Inc., Suzhou (CN)

(72) Inventors: Guoqiao TAO, Suzhou (CN); Peng XIANG, Suzhou (CN); Kai LIU, Suzhou (CN)

(21) Appl. No.: 18/385,220

(22) Filed: Oct. 30, 2023

(30) Foreign Application Priority Data
Mar. 9, 2023 (CN) 202310224954.X

(51) Int. Cl. H01L 29/778; H01L 29/20; H01L 29/423; H01L 29/66

(52) U.S. Cl. CPC H01L 29/7786; H01L 29/2003; H01L 29/42316; H01L 29/66462

(57) ABSTRACT

A semiconductor structure includes a first semiconductor layer, a second semiconductor layer, and a gate. The second semiconductor layer is disposed on the first semiconductor layer. The first semiconductor layer and the second semiconductor layer form a heterostructure. The gate is disposed on the gate region of the second semiconductor layer. In the gate region, multiple spacing layers arranged at intervals are disposed between the second semiconductor layer and the first semiconductor layer along the extension direction of the gate. Each of the spacing layers forms a current path across the length of a channel.

### CROSS-REFERENCE TO RELATED APPLICATION(S)

This application claims the priority to Chinese Patent Application No. CN202310224954.X, filed on Mar. 9, 2023, the disclosure of which is incorporated herein by reference in its entirety.

### TECHNICAL FIELD

Embodiments of the present application relate to the field of semiconductor technologies and, in particular, to a semiconductor structure and a preparation method thereof.

### BACKGROUND

A high electron mobility transistor (HEMT) is a type of field-effect transistor. The high electron mobility transistor forms a heterostructure by using two materials having different energy gaps and has a strong two-dimensional electron gas. The high electron mobility transistor can operate at high frequencies and is therefore widely used in mobile telephones, satellite TV, and radar.

A gallium nitride high-electron-mobility transistor attracts a lot of attention because of good high frequency characteristics of the gallium nitride high-electron-mobility transistor. However, a gallium nitride high-electron-mobility transistor currently has problems of short transconductance stability period and poor linearity. Therefore, how to improve transconductance stability and linearity is an urgent problem to be solved by those skilled in the art.

### SUMMARY

Embodiments of the present application provide a semiconductor structure and a preparation method thereof to improve transconductance stability and linearity of a device.

According to one aspect of the present application, a semiconductor structure is provided. The semiconductor structure includes a first semiconductor layer, a second semiconductor layer, and a gate. The second semiconductor layer is disposed on the first semiconductor layer. The first semiconductor layer and the second semiconductor layer form a heterostructure. The gate is disposed on a gate region of the second semiconductor layer. In the gate region, a plurality of spacing layers arranged at intervals are disposed between the second semiconductor layer and the first semiconductor layer along the extension direction of the gate.

According to another aspect of the present application, a method for preparing a semiconductor structure is provided. The method includes growing a first semiconductor layer; growing a plurality of spacing layers on the first semiconductor layer: growing a second semiconductor layer on the first semiconductor layer, where the first semiconductor layer and the second semiconductor layer form a heterostructure, and the plurality of spacing layers are located between the second semiconductor layer and the first semiconductor layer; and growing a gate in the gate region of the second semiconductor layer, and a plurality of spacing layers are arranged at intervals along an extension direction of the gate.

### BRIEF DESCRIPTION OF DRAWINGS

FIG. 1 is a perspective view of a semiconductor structure according to an embodiment of the present application.

FIG. 2 is a top view of the structure shown in FIG. 1.

FIG. 3 is a sectional view of the structure shown in FIG. 2 taken along section line AA1.

FIG. 4 is a sectional view of the structure shown in FIG. 2 taken along section line BB1.

FIG. 5 is a sectional view of the structure shown in FIG. 2 taken along section line CC1.

FIG. 6 is a sectional view of another semiconductor structure according to an embodiment of the present application.

FIG. 7 is a diagram showing a distribution of a source region, a drain region, and a gate region in the structure shown in FIG. 1.

FIG. 8 is a diagram showing a comparison between an Id-Vg curve of a semiconductor structure provided with an entire spacing layer and an Id-Vg curve of a semiconductor structure not provided with a spacing layer according to an embodiment of the present application.

FIG. 9 is a diagram showing a comparison between a Gm-Vg curve of a semiconductor structure provided with an entire spacing layer, a Gm-Vg curve of a semiconductor structure not provided with a spacing layer, and a Gm-Vg curve of a semiconductor structure provided with spacing layers disposed at intervals according to an embodiment of the present application.

FIG. 10 is a diagram showing an arrangement of spacing layers according to an embodiment of the present application.

FIG. 11 is a diagram showing another arrangement of spacing layers according to an embodiment of the present application.

FIG. 12 is a diagram showing another arrangement of spacing layers according to an embodiment of the present application.

FIG. 13 is a sectional view of another semiconductor structure according to an embodiment of the present application.

FIG. 14 is a sectional view of another semiconductor structure according to an embodiment of the present application.

FIG. 15 is a perspective view of another semiconductor structure according to an embodiment of the present application.

FIG. 16 is a top view of the structure shown in FIG. 15.

FIG. 17 is a sectional view of the structure shown in FIG. 16 taken along section line DD1.

FIG. 18 is a flowchart of a method for preparing a semiconductor structure.

FIG. 19 and FIG. 20 are intermediate structures of a semiconductor structure.

FIG. 21 and FIG. 22 are intermediate structures of a semiconductor structure.

FIG. 23 is a sectional view of another semiconductor structure according to an embodiment of the present application.

### DETAILED DESCRIPTION

For a better understanding of solutions in the present application by those skilled in the art, the technical solutions in embodiments of the present application are described clearly and completely below in conjunction with the drawings in the embodiments of the present application.

It is to be noted that the terms “including”, “having”, or any other variations thereof described herein are intended to encompass a non-exclusive inclusion. For example, a process, method, system, product, or device that includes a series of steps or units may include not only the expressly listed steps or units but also other steps or units that are not expressly listed or are inherent to such a process, method, product, or device.

As in the background, a gallium nitride high-electron-mobility transistor attracts a lot of attention because of good high frequency characteristics of the gallium nitride high-electron-mobility transistor. However, a gallium nitride high-electron-mobility transistor currently has problems of short transconductance stability period and poor linearity. In the related art, linearity is improved by etching the upper surface of a barrier layer. However, the etching process is difficult to control, resulting in device damage in a gate region. Therefore, how to improve transconductance stability and linearity is an urgent problem to be solved by those skilled in the art.

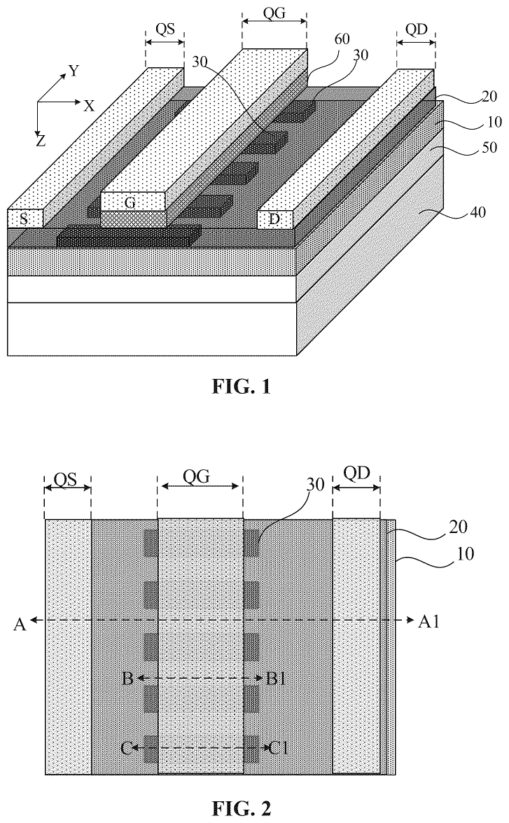

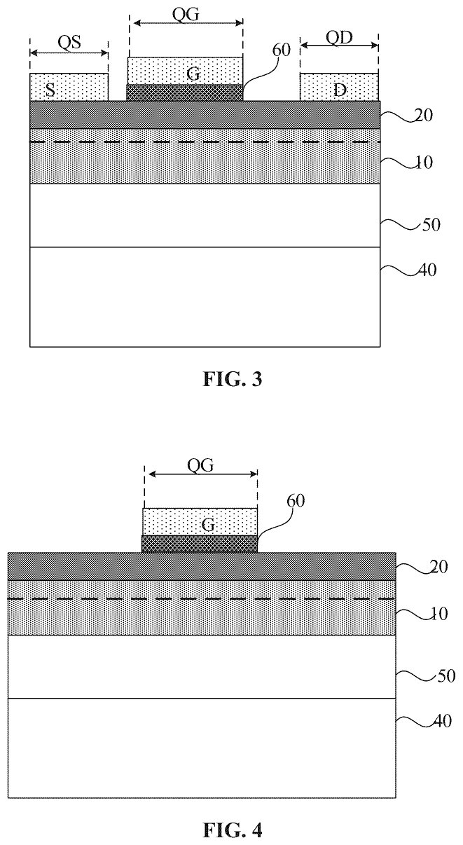

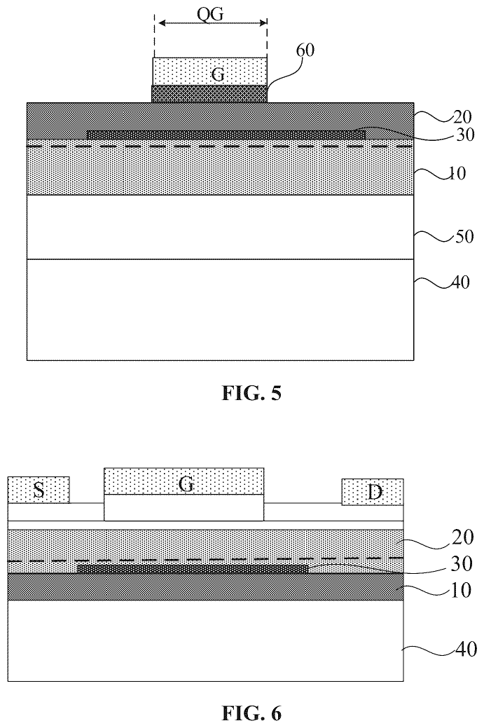

In view of the above, an embodiment of the present application provides a semiconductor structure. FIG. 1 is a perspective view of a semiconductor structure according to an embodiment of the present application. FIG. 2 is a top view of the structure shown in FIG. 1. FIG. 3 is a sectional view of the structure shown in FIG. 2 taken along section line AA1. FIG. 4 is a sectional view of the structure shown in FIG. 2 taken along section line BB1. FIG. 5 is a sectional view of the structure shown in FIG. 2 taken along section line CC1. Referring to FIGS. 1 to 5, the semiconductor structure includes a first semiconductor layer 10, a second semiconductor layer 20, and a gate G.

The second semiconductor layer 20 is disposed on the first semiconductor layer 10. The first semiconductor layer 10 and the second semiconductor layer 20 form a heterostructure.

The gate G is disposed in the gate region QG of the second semiconductor layer 20.

Multiple spacing layers 30 arranged at intervals are disposed between the second semiconductor layer 20 and the first semiconductor layer 10 along the extension direction (direction Y) of the gate G.

In an embodiment, one of the first semiconductor layer 10 and the second semiconductor layer 20 is a wide bandgap semiconductor material and another is a wider bandgap semiconductor material. The first semiconductor layer 10 and the second semiconductor layer 20 are sequentially stacked. The first semiconductor layer 10 and the second semiconductor layer 20 are configured to form a heterostructure. The terms “wide bandgap” and “wider bandgap” used herein describe the bandgap of individual materials relative to each other.

Generally, narrow bandgap refers to a class of semiconductors such as silicon (Si) and germanium (Ge). Gallium nitride (GaN) can be considered as a wide bandgap semiconductor. Aluminum gallium nitride (AlGaN) can be considered as a wider bandgap semiconductor. A wide bandgap semiconductor layer may be a substantially intrinsic semiconductor layer. As used herein, the term “substantially intrinsic” refers to an unintentionally doped semiconductor which may include one or more impurities/dopants unintentionally contained in the semiconductor. A two-dimensional electron gas (2DEG) channel may occur in a wide bandgap semiconductor layer adjacent to the boundary of a wider bandgap semiconductor layer. In an implementation, the wider bandgap semiconductor layer may be a Group III/V semiconductor compound. The wide bandgap semiconductor layer may be a Group III/V semiconductor compound. For example, the wide bandgap semiconductor layer may include gallium nitride (GaN). The wider bandgap semiconductor layer may include aluminum gallium nitride (AlGaN). Most of carriers in the 2DEG channel may be electrons in the heterojunction formed between the AlGaN layer and the GaN layer.

The first semiconductor layer 10 may be a wide bandgap semiconductor material. The second semiconductor layer 20 may be a wider bandgap semiconductor material. Alternatively, the second semiconductor layer 20 may be a wide bandgap semiconductor material. The first semiconductor layer 10 may be a wider bandgap semiconductor material. As shown in FIGS. 3 to 5, when the first semiconductor layer 10 is a wide bandgap semiconductor material and the second semiconductor layer 20 is a wider bandgap semiconductor material, the first semiconductor layer 10 is a channel layer and the second semiconductor layer 20 is a barrier layer. As shown in FIG. 3, the 2DEG channel is illustrated by a dashed line adjacent to the second semiconductor layer 20 at the boundary of the first semiconductor layer 10. The 2DEG channel occurs in the channel layer adjacent to the boundary of the barrier layer. Optionally, the first semiconductor layer 10 is GaN, and the second semiconductor layer 20 is AlGaN.

FIG. 6 is a sectional view of another semiconductor structure according to an embodiment of the present application. Referring to FIG. 6, when a second semiconductor 20 is a wide bandgap semiconductor material and a first semiconductor layer 10 is a wider bandgap semiconductor material, the first semiconductor layer 10 is a back barrier layer and the second semiconductor layer 20 is a channel layer. A 2DEG channel occurs in the channel layer adjacent to the boundary of the back barrier layer. Optionally, the first semiconductor layer 10 is AlGaN, and the second semiconductor layer 20 is GaN.

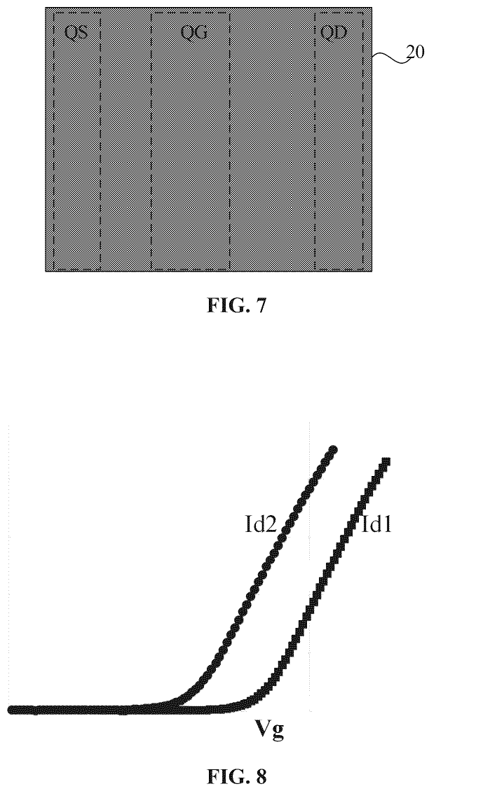

FIG. 7 is a diagram showing a distribution of a source region, a drain region, and a gate region in the structure shown in FIG. 1. The plane shown in FIG. 7 is a plane formed in the direction X and the direction Y. Referring to FIG. 1 and FIG. 7, the semiconductor structure also includes a source region QS, a drain region QD, and a gate region QG. The source region QS is located on a first portion of the second semiconductor layer 20. The drain region QD is located on a second portion of a barrier layer 20. The gate region QG is located on a third portion of the second semiconductor layer 20 between the source region QS and the drain region QD. The semiconductor structure also includes a gate G located in the gate region QG, a source S located in the source region QS, and a drain D located in the drain region QD. In a direction parallel to the first semiconductor layer 10, the source S and the drain D are located on two sides of the gate G.

An entire AlN insertion layer can be generally grown between a channel layer and a barrier layer/back barrier layer. The function of the AlN intercalation layer is to improve the effective conduction band level of the polarization effect of the GaN channel layer and the AlGaN barrier layer/back barrier layer and enhance the polarization effect of the barrier layer, thereby improving the two-dimensional electron gas surface density. On the other hand, the AlN insertion layer can suppress scattering of part of the two-dimensional electron gas penetrated into the AlGaN barrier layer/back barrier layer, thereby improving the mobility of the two-dimensional electron gas. However, whether a semiconductor structure in which an AlN insertion layer is grown on a GaN channel layer or a semiconductor structure in which an AlN insertion layer is not grown on a channel layer, there are problems in that the transconductance stability period is short and the linearity is poor. Transconductance Gm represents the control ability of gate-source voltages (Vgs) to drain current (Id), that is, the ratio of the variation of the drain current to the variation of the gate-source voltages. Moreover, transconductance Gm is an important parameter to weigh the amplification performance of field effect transistor. Linearity refers to a nonlinear error. The smaller the nonlinear error, the higher and better the linearity. The linearity can be reflected in the transconductance stability period. The wider the transconductance stability period, indicating that the linearity is improved. For a conventional GaN HEMT device when operating at a high current, transconductance decreases rapidly, thereby making linearity significantly worse.

In the embodiments of the present application, referring to FIG. 1, in the gate region QG, multiple spacing layers 30 arranged at intervals are disposed between the second semiconductor layer 20 and the first semiconductor layer 10 along the extension direction (direction Y) of the gate G. The AlN insertion layer is arranged as multiple spacing layers 30 arranged at intervals. This is equivalent to forming parallel current paths. Scattering of part of the 2DEG penetrated into the barrier layer is suppressed. Regionalization limits the movement of the 2DEG in the current paths, thereby improving the transconductance stability and the linearity. The material of the spacing layers 30 may also be AlN.

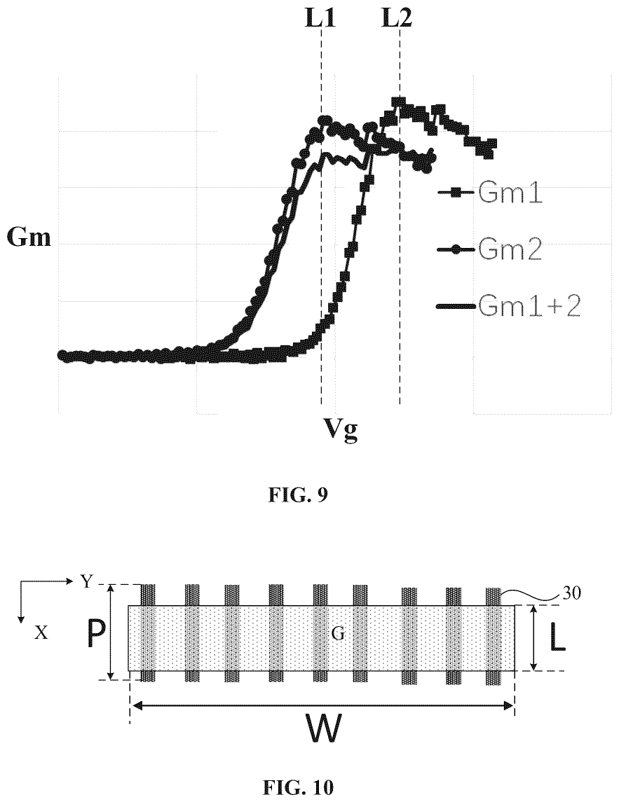

FIG. 8 is a diagram showing a comparison between an Id-Vg curve of a semiconductor structure provided with an entire spacing layer and an Id-Vg curve of a semiconductor structure not provided with a spacing layer according to an embodiment of the present application. FIG. 9 is a diagram showing a comparison between a Gm-Vg curve of a semiconductor structure provided with an entire spacing layer, a Gm-Vg curve of a semiconductor structure not provided with a spacing layer, and a Gm-Vg curve of a semiconductor structure provided with spacing layers disposed at intervals according to an embodiment of the present application. The semiconductor structure provided with an entire spacing layer 30 has a lower threshold voltage. The semiconductor structure without a spacing layer 30 has a higher threshold voltage. Referring to FIG. 8 and FIG. 9, for the semiconductor structure provided with an entire spacing layer 30, the transconductance-gate voltage curve Gm2 starts to fall after the dashed line L1. However, for the semiconductor structure without a spacing layer 30, the transconductance-gate voltage curve Gm1 starts to fall after the dashed line L2 and is still in a rising phase between L1 and L2. In this embodiment of the present application, in the gate region QG, multiple spacing layers 30 arranged at intervals are disposed between the second semiconductor layer 20 and the first semiconductor layer 10 along the extension direction of the gate G. A portion having a spacing layer 30 has a locally lower threshold voltage. A portion without a spacing layer 30 has a locally higher threshold voltage. After spacing layers 30 are disposed at intervals, in conjunction with the curve Gm1 and the curve Gm2, the rise of the curve Gm2 can counteract the fall of the curve Gm1 between the dashed line L1 and the dashed line L2. The overall effect is that the transconductance Gm has a wider plateau period. Thus, the transconductance-gate voltage curve Gm1+2 of the semiconductor structure after the spacing layers 30 are disposed at intervals can have a transconductance stabilization period without allowing the transconductance Gm to decrease rapidly, thereby improving linearity.

According to the semiconductor structure provided in this embodiment of the present application, multiple spacing layers arranged at intervals are disposed between the second semiconductor layer and the first semiconductor layer along the extension direction of the gate. Each of the spacing layers forms a current path across the length of a channel (direction X of the gate region QG). This is equivalent to forming parallel current paths. Positions with spacing layers have higher 2DEG densities and lower threshold voltages. Positions without spacing layers have higher threshold voltages. The scattering of the part of the 2DEG penetrating into the second semiconductor layer or the first semiconductor layer is suppressed. Regionalization limits the movement of the 2DEG in the current paths. Thus, the transconductance stability period is wider, thereby improving the stability of transconductance and improving the linearity of a device. The semiconductor structure may be a high-electron-mobility transistor.

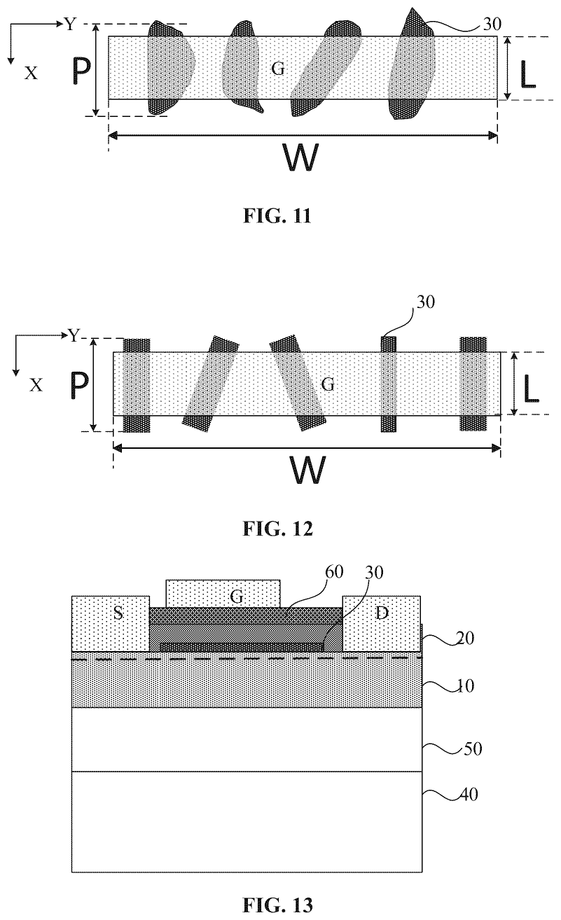

FIG. 10 is a diagram showing an arrangement of spacing layers according to an embodiment of the present application. Referring to FIG. 10, and in conjunction with FIG. 1, in an embodiment of the present application, the length P of a spacing layer 30 is greater than or equal to the length L of the gate G in the extension direction perpendicular to the gate G.

Referring to FIG. 10, in a vertical projection of the second semiconductor layer 20, the gate G has a length L and a width W. In the extension direction perpendicular to the gate G, that is, in the direction X, the length P of a spacing layer 30 is greater than or equal to the length L of the gate G. The extension direction Y of the gate G is the direction of the width of the gate G. If the length P of a spacing layer 30 is less than the length L of the gate G in the extension direction perpendicular to the gate G, a current path across the length of a channel cannot be formed. This causes the threshold voltage to rise, thereby affecting the effect of widening the transconductance stability period and improving the linearity. By setting the length P of a spacing layer 30 to be greater than or equal to the length L of the gate G, a current path across the length of a channel can be formed to reduce the threshold voltage. At a position without a spacing layer 30, the threshold voltage is higher so that the transconductance stabilization period is wider, and the linearity is improved.

In an embodiment of the present application, the projection area of spacing layers 30 in the gate region QG accounts for 20% to 80% of the area of the gate region QG. It is to be understood that the area of the gate region QG is the area of the gate and is equal to the product of the length L and the width W in FIG. 10. The projection area of spacing layers 30 in the gate region QG refers to the area of spacing layers 30 in the region where the gate area is located in FIG. 10.

The spacing layers 30 are grown on the first semiconductor layer 10 to improve the effective conduction band level between the first semiconductor layer 10 and the second semiconductor layer 20 and enhance the polarization effect of the barrier layer, thereby improving the two-dimensional electron gas surface density. On the other hand, the spacing layers 30 can suppress scattering of part of the two-dimensional electron gas penetrated into the AlGaN barrier layer (or the back barrier layer), thereby improving the mobility of the two-dimensional electron gas. If the projection area of the spacing layers 30 in the gate region QG is too small to account for the area of the gate region QG, the two-dimensional electron gas surface density and mobility are affected. Thus, the trend of the transconductance-gate voltage curve Gm1+2 tends to converge toward the trend of the transconductance-gate voltage curve Gm1. If the projection area of the spacing layers 30 in the gate region QG is too larger to account for the area of the gate G, the trend of the transconductance-gate voltage Gm1+2 tends to converge toward the trend of the transconductance-gate voltage curve Gm2. That is, no matter whether the percentage of the projection area of the spacing layers 30 in the gate region QG accounting for the area of the gate G is too large or too small, this has little effect on prolonging the transconductance stability period. In this embodiment of the present application, the projection area of spacing layers 30 in the gate region QG accounts for 20% to 80% of the area of the gate G, thereby effectively improving the stability of transconductance and improving the linearity of a device.

FIG. 11 is a diagram showing another arrangement of spacing layers according to an embodiment of the present application. FIG. 12 is a diagram showing another arrangement of spacing layers according to an embodiment of the present application. Referring to FIGS. 10 to 12, in an embodiment of the present application, patterns of spacing layers 30 include at least one of a polygon, a circle, an ellipse, or a special-shaped pattern. Referring to FIG. 10 and FIG. 12, exemplarily, the pattern of a spacing layer 30 is a rectangle. Referring to FIG. 11, exemplarily, the pattern of a spacing layer 30 is a special-shaped pattern. Multiple spacing layers 30 are sequentially arranged at intervals along the extension direction of the gate. Alternatively, at least one spacing layer 30 is taken as a group, and multiple groups of spacing layers 30 are sequentially arranged at intervals. When two or more spacing layers are included in each group, the distance between two adjacent spacing layers is zero. This is equivalent to increasing the area of the spacing layer.

In an embodiment of the present application, the range of the thickness of a spacing layer 30 is 0.1 to 2 nm. The direction of the thickness is the direction in which the first semiconductor layer 10 points toward the second semiconductor layer 20 (direction Z in FIG. 1). The spacing layer 30 is a multilayer film structure. The range of the thickness of the spacing layer 30 of the multilayer film structure is 0.1 to 2 nm. The spacing layer 30 may also be a single film layer structure formed by depositing an AlN material layer having an atom-level thickness. The range of the thickness of the spacing layer 30 of the single film layer structure is 0.1 to 0.3 nm.

Referring to FIGS. 1 to 5, in an embodiment of the present application, the semiconductor structure also includes a substrate 40 and a buffer layer 50. The buffer layer 50 is located between the substrate 40 and the first semiconductor layer 10.

In an embodiment, the semiconductor structure may also include a substrate 40 on which the first semiconductor layer 10 can be formed. In an implementation, the substrate 40 may be selected from a semiconductor material, a ceramic material, a polymer material, or the like, for example, selected from diamond, sapphire, silicon carbide, silicon, lithium niobate, silicon-on-insulator (SOI), gallium nitride, or aluminum nitride. The semiconductor structure may include a buffer layer 50 between the substrate 40 and the first semiconductor layer 10. Epitaxy refers to a technique of growing new crystals on the substrate 40 to form a semiconductor layer. In the technique of epitaxially growing a group-III-nitride semiconductor layer on the substrate 40, due to the difference between the lattice mismatch and thermal expansion coefficient between the substrate 40 and the group-III-nitride semiconductor layer, it is easy to cause the substrate to deform and cause the group-III-nitride semiconductor layer to crack or the like. In this embodiment of the present application, the buffer layer 50 is formed between the substrate and the group-III-nitride semiconductor layer to reduce the difference in lattice coefficient between the substrate and the group-III-nitride semiconductor layer, thereby reducing the generation of cracks.

In an embodiment of the application, the semiconductor structure also includes a nucleation layer. The nucleation layer is located between the substrate 40 and the buffer layer 50 (not shown).

The thickness mismatch between the buffer layer and the group-III-nitride semiconductor layer can cause defects such as a slip line, bowing, a crack, or even a fragment of the entire semiconductor epitaxial structure. A nucleation layer is selectively formed on the substrate. The nucleation layer may include an AlN layer. The thickness of the nucleation layer may be between 0 nm and 50 nm. The thickness of the nucleation layer may be set to be different so that the bowing rate or curvature of the semiconductor epitaxial structure is less than or equal to a predetermined value, thereby reducing the generation of defects such as a slip line, a crack, and even a fragment, and improving the yield of the semiconductor epitaxial structure.

Referring to FIGS. 1 to 5, in an embodiment of the present application, a source S and a drain D are located on a second semiconductor layer 20. Alternatively, FIG. 13 is a sectional view of another semiconductor structure according to an embodiment of the present application. Referring to FIG. 13, a source S and a drain D penetrate through the second semiconductor layer 20) and are located on the first semiconductor layer 10. The source S and the drain D may include a conductor such as titanium (Ti), titanium nitride (TiN), tungsten (W), titanium tungsten (TiW), molybdenum (Mo), or the like. It is to be noted that FIG. 13 may be a sectional view of FIG. 2 in the direction of CC1.

Referring to FIGS. 1 to 5, in an embodiment of the present application, the semiconductor structure also includes a riser layer 60 located between the second semiconductor layer 20 and the gate G. The electrical function of the riser layer 60 is that electrons exist at the channel layer (the first semiconductor layer 10) and mirror image positive charges exist above the barrier layer (the second semiconductor layer 20). The riser layer 60 can improve the stability of the mirror image positive charges and improve the stability of electrons in the channel. The mechanical function of the riser layer 60 is that the lattice constant of the material AlGaN of the barrier layer is less than the lattice constant of the material GaN of the channel layer. The material of the riser layer 60 is GaN, which can improve stress. The gate G in FIG. 2 blocks the riser layer 60.

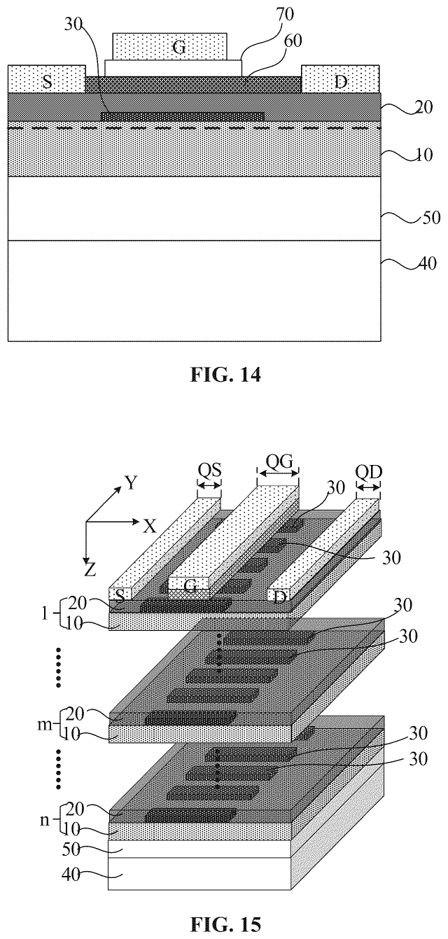

FIG. 14 is a sectional view of another semiconductor structure according to an embodiment of the present application. Referring to FIG. 14, in an embodiment of the present application, a semiconductor structure also includes a p-GaN layer 70 located between a gate G and a second semiconductor layer 20. For example, the p-GaN layer 70 includes a P-type GaN material. When the P—GaN layer 70 is not disposed in the semiconductor structure, the semiconductor structure belongs to a normally turned-on device. When the P—GaN layer 70 is disposed in the semiconductor structure, the 2DEG of the channel layer can be depleted when no voltage is applied. Therefore, in a non-use state, the device is in an off state and belongs to a normally turned-off device or an enhanced device. Referring to FIG. 14, the semiconductor structure includes a riser layer 60 and the p-GaN layer 70. The riser layer 60 is located between the p-GaN layer 70 and the gate G. It is to be noted that FIG. 14 may be a sectional view of FIG. 2 in the direction of CC1.

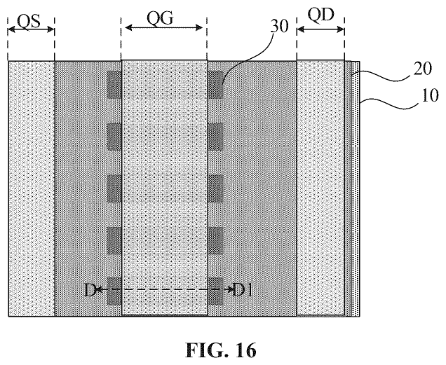

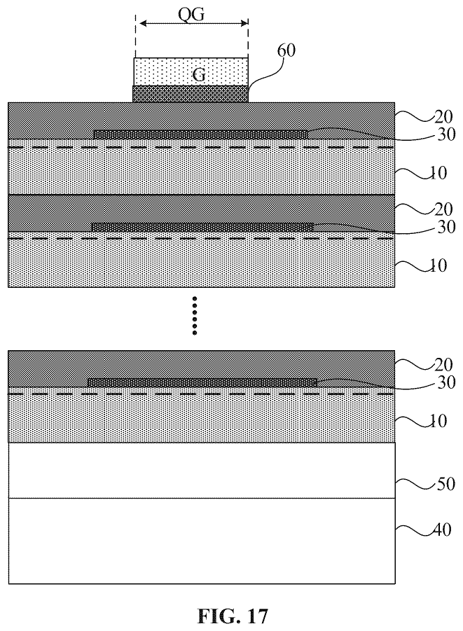

FIG. 15 is a perspective view of another semiconductor structure according to an embodiment of the present application. FIG. 16 is a top view of the structure shown in FIG. 15. FIG. 17 is a sectional view of the structure shown in FIG. 16 taken along section line DD1. Referring to FIGS. 15 to 17, in an embodiment of the present application, the number of first semiconductor layers 10 is n. The number of second semiconductor layers 20 is n. n is an integer greater than or equal to 2. The first semiconductor layers 10 and the second semiconductor layers 20 are arranged alternately in sequence in a direction (direction Z) perpendicular to the first semiconductor layers 10. A gate G is disposed on the gate region QG of a second semiconductor layer 20 located in the uppermost layer. Along the extension direction of the gate G, multiple spacing layers 30 arranged at intervals are disposed between each of the first semiconductor layers 10 and a second semiconductor layer 20 disposed on the each of the first semiconductor layers 10.

It is to be understood that the semiconductor structure includes n groups of first semiconductor layers 10 and second semiconductor layers 20. Thus, a semiconductor structure having a multi-channel layer (n≥2, and n being an integer) can be formed. In the gate region QG, between a first semiconductor layer 10 and a second semiconductor layer 20 in each group, multiple spacing layers 30 sequentially arranged at intervals along the extension direction of the gate G may be disposed. Spacing layers 30 in different groups may be aligned or misaligned. Exemplarily, spacing layers 30 in different groups are aligned in the direction Z in FIG. 15 and FIG. 16.

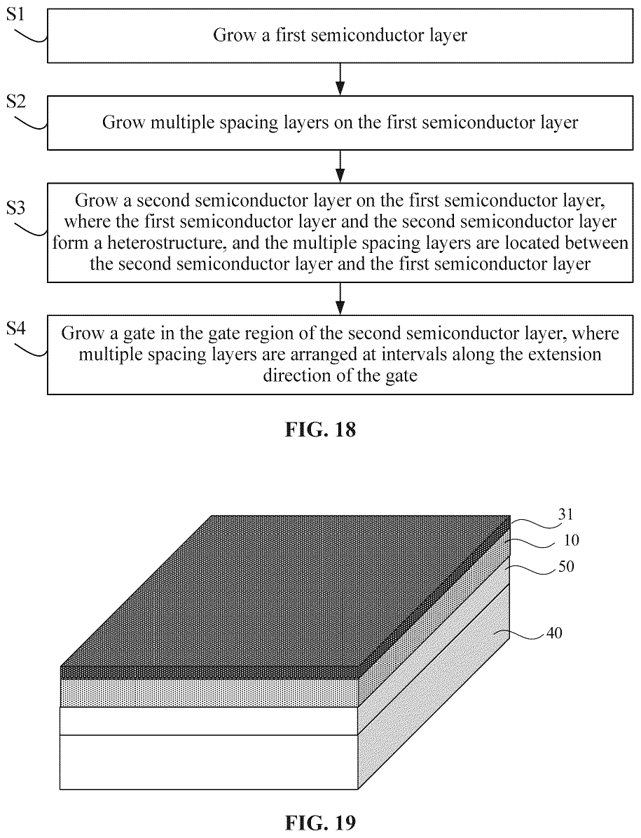

An embodiment of the present application also provides a method for preparing a semiconductor structure used for preparing the semiconductor structure according to any one of the preceding embodiments. FIG. 18 is a flowchart of a method for preparing a semiconductor structure. Referring to FIG. 18, the method includes the following steps. In step S1, a first semiconductor layer 10 is grown. In step S2, multiple spacing layers 30 are grown on the first semiconductor layer 10. In step S3, a second semiconductor layer 20 is grown on the first semiconductor layer 10. The first semiconductor layer 10 and the second semiconductor layer 20 form a heterostructure. The multiple spacing layers 30 are located between the second semiconductor layer 20 and the first semiconductor layer 10. In step S4, a gate G is grown in the gate region QG of the second semiconductor layer 20. Multiple spacing layers 30 are arranged at intervals along the extension direction of the gate G.

In an embodiment of the present application, in step S2, multiple spacing layers 30 are grown, including passing a MO source for a time ≤20 s to shorten the fabrication time to form spacing layers 30 arranged at intervals. Optionally, the material of the spacing layers 30 includes AlN. The MO source may be trimethylaluminum (TMAl) or the like.

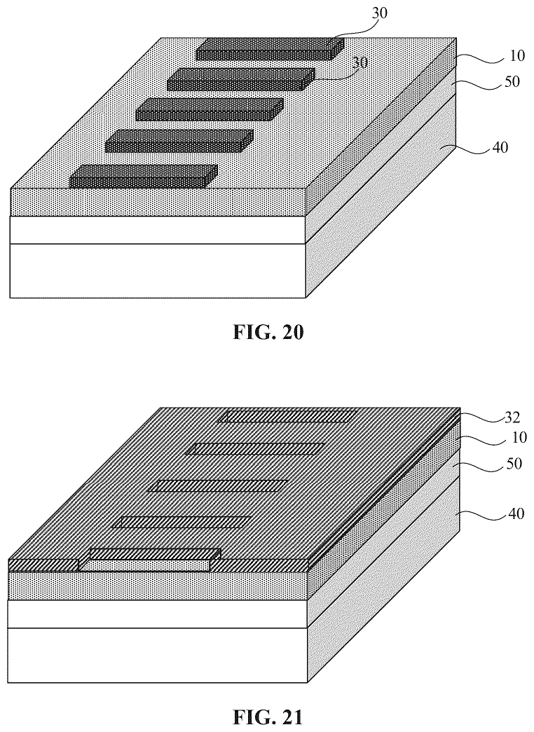

FIG. 19 and FIG. 20 are intermediate structures of a semiconductor structure. In an embodiment of the present application, in step S2, multiple spacing layers 30 are grown, including, referring to FIG. 19, growing a spacing material layer 31 on a first semiconductor layer 10, and referring to FIG. 20, patterning and etching the spacing material layer 31 to obtain spacing layers 30 arranged at intervals. Optionally, the spacing material layer 31 is entirely formed on the first semiconductor layer 10. Part of the spacing material layer 31 is removed through etching. The remaining spacing material layer 31 forms spacing layers 30 arranged at intervals.

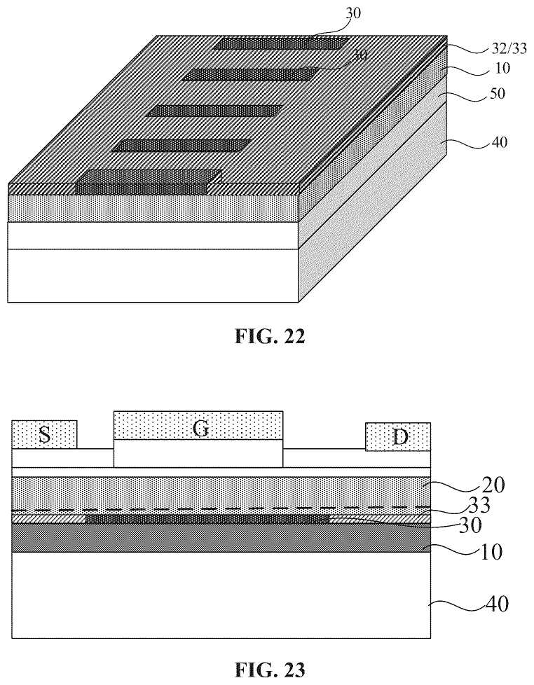

FIG. 21 and FIG. 22 are intermediate structures of a semiconductor structure. In an embodiment of the present application, in step S2, multiple spacing layers 30 are grown, including, referring to FIG. 21, making a patterned mask layer 32 on a first semiconductor layer 10, referring to FIG. 22, selectively growing spacing layers 30 in a region not covered by the mask layer 32, and referring to FIG. 20, etching and removing the mask layer 32 to obtain the spacing layers 30 arranged at intervals. It is to be noted that the lattice quality of the spacing layers 30 formed by first entirely making the spacing material layer 31 and then etching is better than the lattice quality of the selectively grown spacing layers 30.

FIG. 23 is a sectional view of another semiconductor structure according to an embodiment of the present application. In an embodiment of the present application, in step S2, multiple spacing layers 30 are grown, including, referring to FIG. 19, growing a spacing material layer 31 on a first semiconductor layer 10, and referring to FIG. 22, selectively passivating the spacing material layer 31, and converting part of the spacing material layer 31 into a passivation layer 33. Part of the spacing material layer 31 which is not passivated forms spacing layers 30 arranged at intervals. Finally, a semiconductor structure shown in FIG. 23 is made. The spacing layers 30 and the passivation layer 33 are disposed between the first semiconductor layer 10 and a second semiconductor layer 20. It is to be noted that selectivity may be for regions other than the spacing layers 30. The selective passivation process may be local plasma oxidation or ion implantation. Optionally, for example, the material of the spacing layers 30 is AlN. The spacing material layer 31 is AlN. After the selective passivation process, part of the AlN is converted into the passivation layer 33 of the AlON material. The unpassivated AlN is the spacing layers 30.

What is claimed is:

1. A semiconductor structure, comprising:
a first semiconductor layer;
a second semiconductor layer disposed on the first semiconductor layer, wherein the first semiconductor layer and the second semiconductor layer form a heterostructure;
a gate disposed in a gate region of the second semiconductor layer; and
a plurality of spacing layers arranged at intervals and between the second semiconductor layer and the first semiconductor layer along an extension direction of the gate.

2. The semiconductor structure according to claim 1, wherein a length of a spacing layer of the plurality of spacing layers is greater than or equal to a length of the gate in a direction perpendicular to the extension direction of the gate.

3. The semiconductor structure according to claim 1, wherein projection area of the plurality of spacing layers in the gate region accounts for 20% to 80% of area of the gate region.

4. The semiconductor structure according to claim 1, wherein patterns of the plurality of spacing layers comprise at least one of a polygon, a circle, an ellipse, or a special-shaped pattern.

5. The semiconductor structure according to claim 1, wherein a range of a thickness of a spacing layer of the plurality of spacing layers is 0.1 to 2 nm.

6. The semiconductor structure according to claim 5, wherein
the range of the thickness of the spacing layer is 0.1 to 0.3 nm.

7. The semiconductor structure according to claim 1, wherein a material of the plurality of spacing layers comprises AlN.

8. The semiconductor structure according to claim 1, further comprising a substrate and a buffer laver, wherein
the buffer layer is located between the substrate and the first semiconductor layer.

9. The semiconductor structure according to claim 1, wherein
the first semiconductor layer is a channel layer and the second semiconductor layer is a barrier layer; or
the first semiconductor layer is a back barrier layer and the second semiconductor layer is a channel layer.

10. The semiconductor structure according to claim 1, further comprising a source and a drain, wherein
the source and the drain are located on two sides of the gate in a direction parallel to the first semiconductor layer; and
the source and the drain are located above the second semiconductor layer; or the source and the drain penetrate through the second semiconductor layer and are located on the first semiconductor layer.

11. The semiconductor structure according to claim 10, further comprising:
a p-GaN layer located between the gate and the second semiconductor layer.

12. The semiconductor structure according to claim 10, further comprising:
a riser layer located between the gate and the second semiconductor layer.

13. The semiconductor structure according to claim 1, wherein N first semiconductor layers and N second semiconductor layers are provided, wherein N is an integer greater than or equal to 2;
in a direction perpendicular to the first semiconductor layers), the first semiconductor layers and the second semiconductor layers are arranged alternately in sequence; and the gate is disposed in a gate region of a second semiconductor layer of the second semiconductor layers (20) located in an uppermost layer; and
along an extension direction of the gate, a plurality of spacing layers arranged at intervals are disposed between each of the first semiconductor layers and a respective second semiconductor layer which is disposed on each of the first semiconductor layers.

14. A method for preparing a semiconductor structure, comprising:
growing a first semiconductor layer;
growing a plurality of spacing layers on the first semiconductor layer;
growing a second semiconductor layer on the first semiconductor layer, wherein the first semiconductor layer and the second semiconductor layer form a heterostructure, and the plurality of spacing layers are located between the second semiconductor layer and the first semiconductor layer; and
growing a gate in a gate region of the second semiconductor layer, and growing a plurality of spacing layers at intervals along an extension direction of the gate.

15. The preparation method according to claim 14, wherein growing the plurality of spacing layers comprises:
forming the plurality of spacing layers by passing a MO source for a time ≤20 s.

16. The preparation method according to claim 14, wherein growing the plurality of spacing layers comprises:
growing a spacing material layer on the first semiconductor layer, patterning and etching the spacing material layer to obtain the plurality of spacing layers arranged at intervals; or
making a patterned mask layer on the first semiconductor layer, selectively growing the plurality of spacing layers in a region not covered by the mask layer, and etching and removing the mask layer to obtain the plurality of spacing layers arranged at intervals; or
growing a spacing material layer on the first semiconductor layer, selectively passivating the spacing material layer, and converting part of the spacing material layer into a passivation layer, wherein part of the spacing material layer which is not passivated forms the plurality of spacing layers arranged at intervals.
